(19) United States
(12) Patent Application Publication
(10) Pub. No.: US 2006/0017379 A1
(43) Pub. Date: Jan. 26, 2006

(54) Dual-sided display

(75) Inventors: Chih-Hung Su, Hsinchu City (TW); Min-Chieh Hu, Tainan Hsien (TW)

Correspondence Address: BRUCE H. TROXELL, SUITE 1404, 5205 LEESBURG PIKE, FALLS CHURCH, VA, 22041, US

(73) Assignee: AU Optronics Corp.

(21) Appl. No.: 11/136,568

(22) Filed: May 25, 2005

(30) Foreign Application Priority Data
Jul. 23, 2004 (TW) 93122113

(51) Int. Cl. H05B 33/00

(52) U.S. Cl. 313/506

(57) ABSTRACT

A dual-sided display panel includes a first transparent substrate, a second transparent substrate located under the first transparent substrate, a first EL (Electroluminescence) substrate layer, and a second EL layer. The first EL layer is positioned on the bottom surface of the first transparent substrate for displaying a first image on the first transparent substrate. The second EL layer is positioned on the upper surface of the second transparent substrate for displaying a second image on the second transparent substrate. Both the first EL and the second EL are sealed in an airtight space formed between the first transparent substrate and the second transparent substrate.

### BACKGROUND OF THE INVENTION

(1) Field of the Invention

The invention relates to an electro luminescence (EL) display, and more particularly to a dual-sided display of an organic light emitting diode (OLED) display.

(2) Description of the Prior Art

Since the first appearance of a multilayer OLED contributed by Tang and Van Slyke, potential applications of the OLEDs in flat panel displays have been widely acknowledged. Many approaches now have been devoted to constructing a full-color display of the OLEDs.

The OLED can also be called as an organic electro luminescence (OEL). A basic structure of the OLED is a multi-layer organic film laminating a hole-injection layer, a hole-transport layer, an emissive layer and an electron-transport layer. When a voltage is applied to the OLED cell, injected positive and negative charges recombine in the emissive layer and create electro luminescent light.

With advancement of electric appliances, display for the electric appliances is demanding reaction velocity, dots per inch, and pixel quality. Also, light weight and handy size are another trend. For example, the appearance of some dual-sided electric devices explains the urgent need upon a broader viewer to cooperate in the electric devices.

Presently, the dual-sided display is formed by composing two independent LCD displays. Such kind of dual-sided displays has a 8˜10 mm thickness, which is about twice to the thickness of a single display. Definitely, cost for constructing the conventional dual-sided display is also twice to that for constructing the single-sided display. Hence, this kind of the dual-sided displays is hard to be among the master stream of the displays.

FIG. 1 shows a cross-section view of a typical conventional dual-sided OLED display. The OLED display 1 is obtained by assembling two OLED sealing structures 11 and 12. Each of the sealing structures 11, 12 comprises respectively an EL layer 111 or 121, an upper substrate 112 or 122, and an under plate 113 or 123.

As shown, between the upper substrate 112 and the under plate 113, an interior space 114 (exaggerated in thickness) is formed to accommodate the EL substrate 111 disposed under the upper substrate 112 and a desiccant layer 116 disposed above the under plate 113 but under the EL substrate 111. The interior space 114 is mainly contributed by a shallow cavity formed at the under plate 113 by etching or any relevant machining. Also, it is noted that the upper substrate 112 is sealed on the under plate 113 via a sealing material 115. The desiccant layer 116 positioned on the base 114a of the cavity of the under plate 113 is introduced to lower the humidity levels of the airtight space 114.

Elements of the sealing structure 12 are basically the same as those of the sealing structure 11, but presenting a mirror image arrangement with respect to the boarder line in between. The sealing structure 12 comprises an EL layer 121, an upper substrate 122 and an under plate 123. The EL substrate 121 is disposed on the upper substrate 122, and an airtight interior space 124 is formed in the sealing structure 12 by shaping a respective cavity in the under plate 123. The upper substrate 122 is sealed on the under plate 123 via a sealing material 125 so as to form the airtight space 124 for accommodating the EL layer 121 and the desiccant layer 126.

In the art, the thickness of the dual-sided panel 1 is around 3 mm, which is a little too thick to be a so-called film structure. Also, the cost and weight of the dual-sided panel 1 may also make the panel 1 less competitive. Accordingly, an improvement upon the OLED dual-sided display which provides a thinner and larger screen but with a simple production process and a lower cost is definitely welcome to the skill in the art.

### SUMMARY OF THE INVENTION

It is an object of the present invention to provide a dual-sided display of an OLED display.

It is another object of the present invention to provide a dual-sided display with equal luminescent efficiency.

The dual-sided display panel in accordance with the present invention includes a first transparent substrate, a second transparent substrate, a first EL layer, and a second EL layer. Wherein the second transparent substrate is disposed under and sealed to the first transparent substrate, thereby forming an airtight space therebetween. The first EL layer and the second EL layer are both positioned between the first transparent substrate and the second transparent substrate. The first EL layer is disposed in the airtight space and positioned on a bottom surface of the first transparent substrate for displaying a first image through the first transparent substrate. The second EL layer is disposed in the airtight space and positioned on an upper surface of the second transparent substrate and displays a second image through the second transparent substrate. In particular, the area of the first EL layer is larger than the area of the second EL layer.

In the present invention, all the EL layers mentioned above can be composed of the organic light emitting diodes (OLED) or polymer light emitting diodes (PLED). The thickness of the dual-sided display of the invention can be reduced to range about 0.6-1.4 mm. By comparing to the conventional dual-sided OLED display, the manufacturing process to obtain the dual-sided display according to the present invention can be simplified, and the cost for producing the present dual-sided display can be thus reduced.

### BRIEF DESCRIPTION OF THE DRAWINGS

The present invention will now be specified with reference to its preferred embodiment illustrated in the drawings, in which

FIG. 1 is a cross-section view of a conventional OLED display;

FIG. 2 is a cross-section view of a first preferred embodiment of the dual-sided OLED display of the present invention;

FIG. 3 is a cross-section view of a second preferred embodiment of the OLED display of the present invention;

FIG. 4 is a cross-section view of a third preferred embodiment of the OLED display of the present invention; and

FIG. 5 is a cross-section view of a fourth preferred embodiment of the OLED display of the present invention.

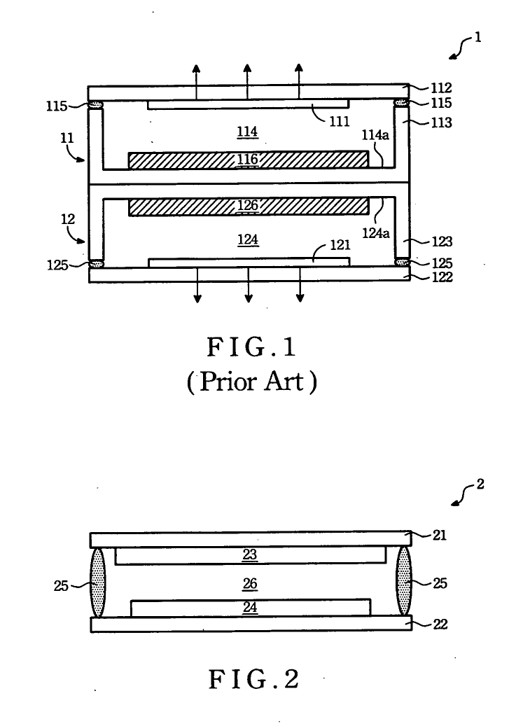

### DESCRIPTION OF THE PREFERRED EMBODIMENT

As mentioned in the foregoing section, a need in improving the OLED dual-sided display to achieve a thinner and larger screen with a simple production process and a lower cost is obvious.

FIG. 2 shows a cross-section view of a first preferred embodiment of the dual-sided display of the present invention. As shown, the dual-sided display 2 comprises a first transparent substrate 21, a second transparent substrate 22, a first EL layer 23, and a second EL layer 24.

The second transparent substrate layer 22 is disposed under and sealed to the first transparent substrate, thereby forming an airtight space 26 therebetween. The first EL layer 23 is disposed on the bottom surface of the first transparent substrate 21, for displaying a first image through the first transparent substrate 21. The second EL layer 24 is disposed in the airtight space 26 and positioned on the upper surface of the second transparent substrate 22, for displaying a second image through the second transparent substrate 22. The first transparent substrate 21 is sealed in a perimeter wise to the second transparent substrate 22 with a sealing material 25 such that an internal airtight space 26 can be formed between the first transparent substrate 21 and the second transparent substrate 22 for accommodating the EL layers 23,24.

In the present invention, the area of the first EL layer 23 and the area of the second EL layer 24 are not always the same. Basically, the sizes and the related positioning of these two EL layer 23,24 can be varied to comply with different kinds of electric devices. In the first preferred embodiment of the invention, the first EL layer 23 is larger in area than the second EL layer 24.

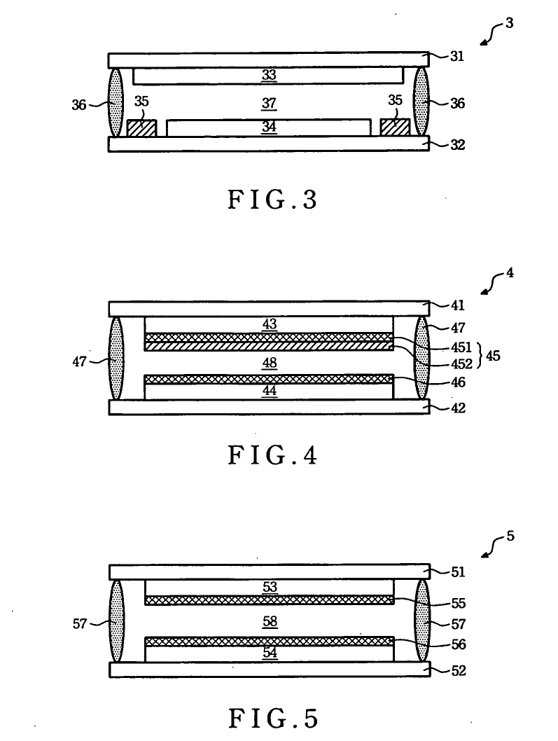

FIG. 3 shows a cross-section view of a second preferred embodiment of the dual-sided OLED display of the present invention.

As shown, the dual-sided display 3 comprises a first transparent substrate 31, a second transparent substrate 32, a first EL layer 33, a second EL layer 34, and a-desiccant layer 35.

The second transparent substrate layer 32 is disposed under and sealed to the first transparent substrate, thereby forming an airtight space 37 therebetween. The first EL layer 33 is disposed in the airtight space 37 and positioned on a bottom surface of the first transparent substrate 31 for displaying a first image through the first transparent substrate 31. The second EL layer 34 is disposed n the airtight space 37 and positioned on an upper surface of the second transparent substrate 32 for displaying a second image on the second transparent substrate 32. The first transparent substrate 31 is sealed on top of the second transparent substrate 32 with a circling sealing material 36 so as to obtain an airtight space 37 in between first transparent substrate for accommodating thereinside the EL layers 33,34.

The first EL layer 23 is larger in area than the second EL layer 24. The area of the substrate 31 or 32 which overlaps with the EL layer 33 or 34 is defined as a display area, and the rest area of the substrate is defined as a non-display area. As shown, the desiccant layer 35 is located in the airtight space and positioned on the non-display area of the upper surface of the second transparent substrate layer 32.

The desiccant layer 35 can lower the humidity level of the airtight space 37 and thus prevent the EL layers 33,34 from possible moisture damage. The desiccant layer 35 on the non-display area of the second transparent substrate layer 32 can be formed by evaporating or sputtering. Upon such an arrangement, the existence of the desiccant layer 35 can show little effect to the thickness of the display 3.

Except for positioning the desiccant layer 35 on the non-display area, the desiccant layer 35 can also be positioned on the display area or across the display area and the non-display area, especially to meet a high humidity environment.

In the present invention, the desiccant layer 35 is made of a material selected from the group consisting of active metals, metallic oxides, and metallic sulfides. The ELs 33,34 can be OLEDs or PLEDs.

Additionally, the drive mode of the present invention can be a mode of passive matrix, a mode of active matrix, or a mixed mode of the passive matrix and the active matrix. The dual-sided display of the invention can be applied to a monochrome display, a polychrome display, or a full-colored display.

FIG. 4 shows a cross-section view of a third preferred embodiment of the dual-sided OLED display of the present invention. As shown, the dual-sided display 4 comprises a first transparent substrate 41, a second transparent substrate 42, a first EL layer 43, a second EL layer 44, a first protection layer 45, and a second protection layer 46.

The second transparent substrate layer 42 is disposed under and sealed to the first transparent substrate 41, thereby forming an airtight space 48 therebetween. The first EL layer 43 is disposed in the airtight space 48 and positioned on a bottom surface of the first transparent substrate 41 for displaying a first image through the first transparent substrate 41. The second EL layer 44 is disposed in the airtight space 48 and positioned on an upper surface of the second transparent substrate 42 for displaying a second image through the second transparent substrate 42.

The first protection layer 45 is positioned on a bottom surface of the first EL layer 43, and the second protection layer 46 is positioned on an upper surface of the second EL layer 44. The first protection layer 45 is comprised of a first barrier layer 451 and a desiccant layer 452, and the second protection layer 46 is comprised of another barrier layer. As shown, the first barrier layer 451 is laminated between the first EL 43 and the desiccant layer 452. The desiccant layer 452 positioned on a bottom surface of the first barrier layer 451 can be formed by evaporating or sputtering.

The first transparent substrate 41 is sealed to the second transparent substrate 42 by a sealing material 47 and thus an airtight space 48 can be formed between the first transparent substrate 41 and the second transparent substrate 42 for accommodating the EL layers 43,44.

The mentioned desiccant layer 452 can be a hydroscopic agent selected from the group of active metals, metallic oxides, and metallic sulfides.

The barrier layer, 451 or 46, is used to provide the EL layer, 43 or 44 respectively, from possible damage of chemical materials which may come from the desiccant layer absorbing ambient mist. The material for the barrier layer 451 or 46 can be selected from the group consisting of nonconductors (such as SiN—SiO—SiC) and low activity metals (for example, Ag—Ti). By adding the desiccant layer 452, the lifetime of the dual-sided display 4 can be substantially prolonged.

In this embodiment, the first EL layer 43 has a surface area the same as that of the second EL layer 44, and the desiccant layer 452 extends to cover all over the barrier layer 451 that has an area about equal to that of the first EL 43. In the case that the relative sizing of the first and the second ELs 43,44 is changed to leave a sufficient room for the desiccant layer 452 to surround either the first EL 43 or the second EL 44, the desiccant layer 452 can be alternatively positioned on the non-display area as described in the foregoing second preferred embodiment.

In the present invention, the existence of the barrier layers 451,46 for protecting the EL layers 43,44 lessens the need of the desiccant layer 452. Please refer to FIG. 5, which shows a cross-section view of a fourth preferred embodiment of the OLED display of the present invention.

Referring to FIG. 5, the dual-sided display 5 comprises a first transparent substrate 51, a second transparent substrate 52, a first EL layer 53, a second EL layer 54, a first barrier layer 55, and a second barrier layer 56. As shown, the arrangement of the dual-sided display 5 in FIG. 5 is exact the same as that shown in FIG. 4, except that the desiccant layer is removed in this fourth embodiment 5.

In the embodiment, either the first barrier layer 55 or the second barrier layer 56 can be a desiccant layer.

In the present invention, all the EL layers mentioned above can be composed of organic light emitting diodes (OLED) or polymer light emitting diodes (PLED). The thickness of the dual-sided display of the invention can be reduced to range about 0.6-1.4 mm, which is thinner than that mentioned in the prior art. Additionally, one more advantage of the invention is that the production cost can be lowered and the manufacturing process can be much simpler than the conventional process of composing two independent OLED displays.

While the present invention has been particularly shown and described with reference to a preferred embodiment, it will be understood by those skilled in the art that various changes in form and detail may be without departing from the spirit and scope of the present invention.

We claim:

1. A dual-sided display comprising:
a first transparent substrate;
a second transparent substrate disposed under and sealed to the first transparent substrate, thereby forming an airtight space therebetween;
a first electro luminescence (EL) layer, disposed in the airtight space and positioned on the bottom surface of the first transparent substrate, for displaying a first image through the first transparent substrate; and
a second EL layer, disposed in the airtight space and positioned on the upper surface of the second transparent substrate, for displaying a second image through the second transparent substrate.

2. The dual-sided display according to claim 1, wherein the area of the first EL layer is larger than the area of the second EL layer.

3. The dual-sided display according to claim 1, wherein the thickness of the dual-sided display is about 0.6 mm to 1.4 mm.

4. The dual-sided display according to claim 1, wherein the first EL layer is comprised of organic light emitting diodes (OLEDs) or polymer light emitting diodes (PLEDs).

5. The dual-sided display according to claim 1, further comprising a desiccant layer located in the airtight space.

6. The dual-sided display according to claim 5, wherein the desiccant layer is made of a material selected from the group consisting of active metals, metallic oxides, and metallic sulfides.

7. The dual-sided display according to claim 5, further comprising a barrier layer formed on the bottom surface of the first EL layer so as to isolate the first EL layer from the desiccant layer.

8. The dual-sided display according to claim 7, wherein the barrier layer is made of a material selected from the group consisting of nonconductors and low activity metals.

9. The dual-sided display according to claim 5, further comprising a second barrier layer formed on the upper surface of the second EL layer so as to isolate the second EL layer from the desiccant layer.

10. The dual-sided display according to claim 9, wherein the second barrier layer is made of a material selected from the group consisting of nonconductors and low activity metals.

11. The dual-sided display according to claim 1, further comprising:
a first protection layer formed on the bottom surface of the first EL layer; and
a second protection layer formed on the upper surface of the second EL layer.

12. The dual-sided display according to claim 11, wherein the first protection layer is comprised of a barrier layer.

13. The dual-sided display according to claim 12, wherein the first protection layer is comprised of nonconductors or low activity metals.

14. The dual-sided display according to claim 11, wherein the first protection layer is comprised of a desiccant layer.

15. The dual-sided display according to claim 14, wherein the first protection layer is comprised of active metals, a metallic oxides, or a metallic sulfides.

16. The dual-sided display according claim 11, wherein the first protection layer comprises a barrier layer disposed on the first EL layer, and a desiccant layer disposed on the barrier layer.

17. The dual-sided display according to claim 11, wherein the second protection layer is comprised of a barrier layer.

18. The dual-sided display according to claim 17, wherein the second protection layer is made of a material selected from the group consisting of nonconductors and low activity metals.

19. The dual-sided display according to claim 11, wherein the second protection layer is comprised of a desiccant layer.

20. The dual-sided display according to claim 19, wherein the second protection layer is comprised of active metals, metallic oxides, or metallic sulfides.
